(19) United States
(12) Patent Application Publication
(10) Pub. No.: US 2021/0351800 A1
(43) Pub. Date: Nov. 11, 2021

(54) RADIO-FREQUENCY MODULE AND COMMUNICATION APPARATUS

(71) Applicant: Murata Manufacturing Co., Ltd., Kyoto (JP)

(72) Inventor: Shinichiro TAKAYANAGI, Kyoto (JP)

(21) Appl. No.: 17/382,487

(22) Filed: Jul. 22, 2021

Related U.S. Application Data
(63) Continuation of application No. PCT/JP2020/007140, filed on Feb. 21, 2020.

(30) Foreign Application Priority Data
Mar. 29, 2019 (JP) 2019-066649

(51) Int. Cl. H04B 1/10; H04B 1/04; H04B 1/00

(52) U.S. Cl. CPC H04B 1/1036; H04B 1/0458; H04B 2001/0408; H04B 1/0078; H04B 2001/1063; H04B 1/0057

(57) ABSTRACT

To achieve space saving and a reduction in cost. A radio-frequency module includes a band pass filter, a first low noise amplifier, a second low noise amplifier, and an attenuation filter. The band pass filter has an output terminal and allows the passage of a first reception signal and a second reception signal. The first low noise amplifier is connected to the output terminal of the band pass filter and amplifies the first reception signal. The second low noise amplifier is connected to the output terminal of the band pass filter and amplifies the second reception signal. The attenuation filter is provided on a common path between the output terminal of the band pass filter and the first low noise amplifier and between the output terminal of the band pass filter and the second low noise amplifier.

### CROSS REFERENCE TO RELATED APPLICATION

This is a continuation of International Application No. PCT/JP2020/007140 filed on Feb. 21, 2020 which claims priority from Japanese Patent Application No. 2019-066649 filed on Mar. 29, 2019. The contents of these applications are incorporated herein by reference in their entireties.

### BACKGROUND

### Technical Field

The present disclosure generally relates to a radio-frequency module and a communication apparatus. In particular, the present disclosure relates to a radio-frequency module including a band pass filter and multiple low noise amplifiers (LNAs) and a communication apparatus including the radio-frequency module.

Radio-frequency modules performing communication of signals in multiple communication bands through carrier aggregation have hitherto been known (for example, refer to Patent Document 1).

The radio-frequency module described in Patent Document 1 includes a filter, a low noise amplifier (LNA), and a resonant filter (attenuation filter) for each of multiple reception signals. The low noise amplifier amplifies part of the reception signal from the filter. The resonant filter is composed so as to remove the signal components in at least one frequency band, which is not amplified by the low noise amplifier.

Patent Document 1: U.S. Pat. No. 10,009,054

### BRIEF SUMMARY

However, in the radio-frequency module in the related art, which is described in Patent Document 1, it is necessary to provide the attenuation filter attenuating unnecessary components (for example, harmonic wave components) for each of the reception signals in the multiple communication bands. In other words, it is necessary to provide the attenuation filters of the number corresponding to the number of the communication bands. In this case, the increased number of the components prevents space saving to increase the cost.

The present disclosure provides a radio-frequency module and a communication apparatus capable of achieving the space saving and a reduction in cost.

A radio-frequency module according to one aspect of the present disclosure includes a band pass filter, a first low noise amplifier, a second low noise amplifier, and an attenuation filter. The band pass filter has an output terminal and allows the passage of a first reception signal and a second reception signal. The first low noise amplifier is connected to the output terminal of the band pass filter and amplifies the first reception signal. The second low noise amplifier is connected to the output terminal of the band pass filter and amplifies the second reception signal. The attenuation filter is provided on a common path between the output terminal of the band pass filter and the first low noise amplifier and between the output terminal of the band pass filter and the second low noise amplifier.

A communication apparatus according to one aspect of the present disclosure includes the radio-frequency module and a signal processing circuit. The signal processing circuit processes the first reception signal and the second reception signal.

With the radio-frequency module and the communication apparatus according to the above aspects of the present disclosure, it is possible to achieve space saving and a reduction in cost.

### BRIEF DESCRIPTION OF THE SEVERAL VIEWS OF THE DRAWINGS

FIG. 1 is a schematic circuit diagram of a radio-frequency module and a communication apparatus according to an embodiment.

FIG. 2 is a circuit diagram of an attenuation filter in the radio-frequency module in FIG. 1.

FIG. 3 is a graph indicating an attenuation characteristic of the attenuation filter in FIG. 2.

FIG. 4 is a circuit diagram of an attenuation filter in a radio-frequency module according to a modification of the embodiment.

FIG. 5 is a graph indicating an attenuation characteristic of the attenuation filter in FIG. 4.

### DETAILED DESCRIPTION

A radio-frequency module and a communication apparatus according to an embodiment will herein be described with reference to the drawings. In this description, “a component (hereinafter referred to as “a first component”) is connected to another component (hereinafter referred to as “a second component”)” includes a case in which “the first component is electrically connected to the second component”. The case in which “the first component is electrically connected to the second component” means a case in which the first component is capable of being electrically connected to the second component and it is not considered whether current actually flows between the first component and the second component. Specifically, the case in which “ the first component is electrically connected to the second component” includes a case in which the first component is directly connected to the second component and a case in which the first component is indirectly connected to the second component with, for example, at least one conductive member or at least one circuit element. The case in which “the first component is indirectly connected to the second component” includes a case in which a circuit element is provided on a path between the first component and the second component. The “circuit element” is exemplified by a switch, a filter, a matching circuit, and a coupler. When the “circuit element” is a switch, it is not considered whether the path between the first component and the second component is connected with the switch or whether the path is disconnected.

### Embodiment

### (1) Radio-Frequency Module

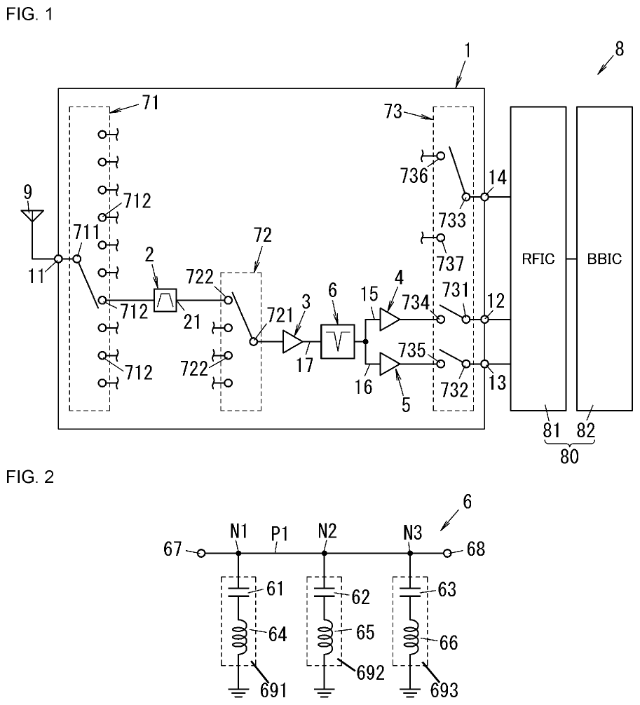

The configuration of a radio-frequency module 1 according to an embodiment will now be described with reference to FIG. 1.

The radio-frequency module 1 according to the embodiment includes a band pass filter 2, a common low noise amplifier (LNA) 3, a first low noise amplifier 4, a second low noise amplifier 5, and an attenuation filter 6, as illustrated in FIG. 1. The radio-frequency module 1 also includes multiple switches 71 to 73, a common terminal 11, and multiple terminals 12 to 14.

The radio-frequency module 1 is used for concurrent use of communication of a first reception signal and communication of a second reception signal. In the embodiment, the first reception signal is a signal conforming to a Fourth Generation (4G) standard and the second reception signal is a signal conforming to a Fifth Generation (5G) standard. Accordingly, the radio-frequency module 1 according to the embodiment supports the concurrent use of communication of the signal conforming to the 4G standard and communication of the signal conforming to the 5G standard. In other words, in the embodiment, the radio-frequency module 1 supports dual connectivity.

The radio-frequency module 1 is used for a mobile phone, such as a smartphone. The radio-frequency module 1 is not limited to the mobile phone and may be used for, for example, a wearable terminal, such as a smartwatch. In sum, the radio-frequency module 1 is used in a communication apparatus 8 communicating with an externa apparatus (not illustrated in FIG. 1).

### (2) Components in Radio-Frequency Module

The respective components in the radio-frequency module 1 according to the embodiment will now be described with reference to the drawing.

### (2.1) Common Terminal

The common terminal 11 is electrically connected to an antenna 9, as illustrated in FIG. 1. In the example in FIG. 1, the common terminal 11 is directly connected to the antenna 9. The common terminal 11 is not limited to the direct connection to the antenna 9 and may be indirectly connected to the antenna 9. Specifically, a circuit, such as a matching circuit, or a circuit element may be provided between the common terminal 11 and the antenna 9.

### (2.2) Terminals

The multiple terminals 12 to 14 are electrically connected to a radio-frequency (RF) signal processing circuit 81 described below, as illustrated in FIG. 1. In other words, the multiple terminals 12 to 14 are directly or indirectly connected to the RF signal processing circuit 81.

### (2.3) Band Pass Filter

The band pass filter 2 has an output terminal 21, as illustrated in FIG. 1, and allows the passage of the first reception signal and the second reception signal. More specifically, the band pass filter 2 is a reception filter that allows the passage of only the reception signals including the first reception signal and the second reception signal. The band pass filter 2 is provided in a common portion (on a common path 17) of a first transmission path 15 and a second transmission path 16. The first transmission path 15 is a transmission path for receiving the first reception signal via the common terminal 11. The first transmission path 15 is formed between the output terminal 21 of the band pass filter 2 and the first low noise amplifier 4. The second transmission path 16 is a transmission path for receiving the second reception signal via the common terminal 11. The second transmission path 16 is formed between the output terminal 21 of the band pass filter 2 and the second low noise amplifier 5.

The band pass filter 2 allows the passage of both the first reception signal in a first reception band and the second reception signal in a second reception band. The second reception band is different from the first reception band. The first reception band is, for example, Band 20 (reception band: 791 MHz to 821 MHz) conforming to the 4G standard. The second reception band is, for example, Band 28A (reception band: 758 MHz to 788 MHz) conforming to the 5G standard. In this case, the second reception band is part of the frequency band of the first reception band.

### (2.4) First Low Noise Amplifier

The first low noise amplifier 4 is electrically connected to the output terminal 21 of the band pass filter 2, as illustrated in FIG. 1, and amplifies the first reception signal. More specifically, the first low noise amplifier 4 is connected to the output terminal 21 of the band pass filter 2 via the first transmission path 15. In the embodiment, the switch 72, the common low noise amplifier 3, and the attenuation filter 6 are provided on the first transmission path 15. Accordingly, the first reception signal, which has passed through the band pass filter 2, has been amplified by the common low noise amplifier 3, and has passed through the attenuation filter 6, is input into the first low noise amplifier 4. The first low noise amplifier 4 amplifies the first reception signal that has passed through the attenuation filter 6. The first reception signal amplified by the first low noise amplifier 4 is supplied to the RF signal processing circuit 81.

### (2.5) Second Low Noise Amplifier

The second low noise amplifier 5 is electrically connected to the output terminal 21 of the band pass filter 2, as illustrated in FIG. 1, and amplifies the second reception signal. More specifically, the second low noise amplifier 5 is connected to the output terminal 21 of the band pass filter 2 via the second transmission path 16. In the embodiment, the switch 72, the common low noise amplifier 3, and the attenuation filter 6 are provided on the second transmission path 16. Accordingly, the second reception signal, which has passed through the band pass filter 2, has been amplified by the common low noise amplifier 3, and has passed through the attenuation filter 6, is input into the second low noise amplifier 5. The second low noise amplifier 5 amplifies the second reception signal that has passed through the attenuation filter 6. The second reception signal amplified by the second low noise amplifier 5 is supplied to the RF signal processing circuit 81.

### (2.6) Attenuation Filter

The attenuation filter 6 is provided on the common path 17, as illustrated in FIG. 1, and attenuates harmonic wave components of the first reception signal and harmonic wave components of the second reception signal. More specifically, the attenuation filter 6 is connected to the output terminal 21 of the band pass filter 2 via the common path 17. The common path 17 is a transmission path formed between the output terminal 21 of the band pass filter 2 and the first low noise amplifier 4 and between the output terminal 21 of the band pass filter 2 and the second low noise amplifier 5. In other words, the common path 17 is the common portion of the first transmission path 15 and the second transmission path 16. In the embodiment, the switch 72 and the common low noise amplifier 3 are provided on the common path 17. Accordingly, the first reception signal and the second reception signal, which have passed through the band pass filter 2 and have been amplified by the common low noise amplifier 3, are input into the attenuation filter 6. The attenuation filter 6 attenuates the harmonic wave components of the first reception signal amplified by the common low noise amplifier 3. The first reception signal the harmonic wave components of which are attenuated by the attenuation filter 6 passes on the first transmission path 15 and is supplied to the first low noise amplifier 4. Similarly, the attenuation filter 6 attenuates the harmonic wave components of the second reception signal amplified by the common low noise amplifier 3. The second reception signal the harmonic wave components of which are attenuated by the attenuation filter 6 passes on the second transmission path 16 and is supplied to the second low noise amplifier 5.

The attenuation filter 6 of the present embodiment is a notch filter illustrated in FIG. 2. The attenuation filter 6 includes multiple (three in the example in FIG. 2) capacitors 61 to 63, multiple (three in the example in FIG. 2) inductors 64 to 66, an input terminal 67, and an output terminal 68.

The capacitor 61 is connected in series to the inductor 64 to compose a series circuit 691. The series circuit 691 is provided between a node N1 on a path P1 between the input terminal 67 and the output terminal 68 and ground.

The capacitor 62 is connected in series to the inductor 65 to compose a series circuit 692. The series circuit 692 is provided between a node N2 on the path P1 and the ground. The series circuit 692 is connected in parallel to the series circuit 691. The node N2 is positioned at the output terminal 68 side, compared with the node N1, on the path P1. Accordingly, the series circuit 692 is provided at the output terminal 68 side, compared with the series circuit 691, on the path illustrated in FIG. 2.

The capacitor 63 is connected in series to the inductor 66 to compose a series circuit 693. The series circuit 693 is provided between a node N3 on the path P1 and the ground. The series circuit 693 is connected in parallel to the series circuit 692. The node N3 is positioned at the output terminal 68 side, compared with the node N2, on the path P1. Accordingly, the series circuit 693 is provided at the output terminal 68 side, compared with the series circuit 692.

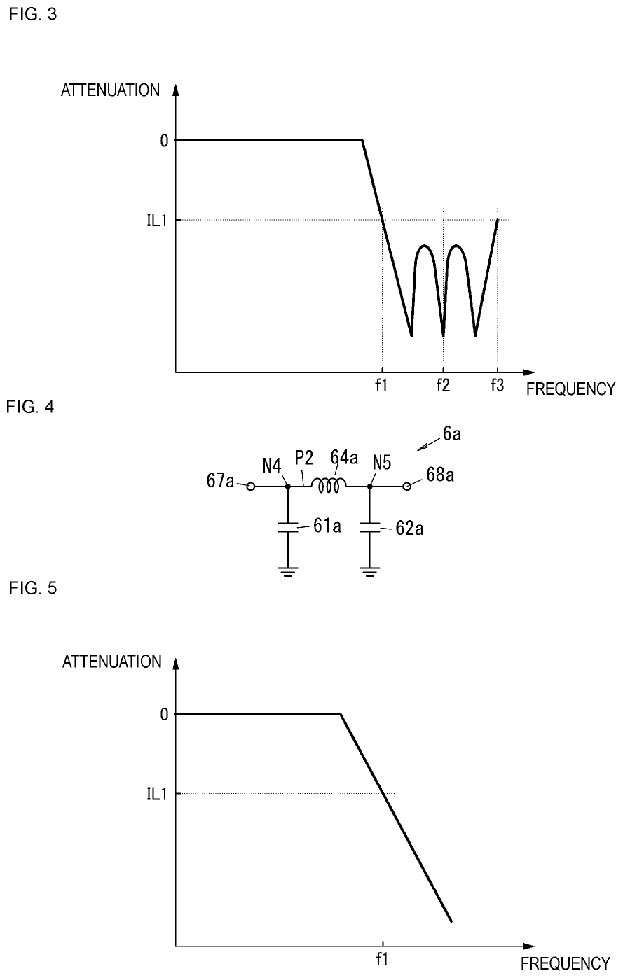

The attenuation filter 6 has an attenuation characteristic illustrated in FIG. 3 because the attenuation filter 6 has the circuit configuration illustrated in FIG. 2. FIG. 3 indicates level representation with respect to the attenuation. Specifically, the attenuation at each frequency is represented by the logarithm of the ratio with respect to the attenuation at the lower-side frequency. The attenuation filter 6 is designed so that the attenuation in a frequency band (including a frequency f2) between a frequency f1 and a frequency f3 is lower than or equal to necessary attenuation IL1 [dB]. The frequency f1 is a frequency twice the lower frequency, among the lower limit frequency of the first reception band and the lower limit frequency of the second reception band. The frequency f3 is a frequency twice the higher frequency, among the upper limit frequency of the first reception band and the upper limit frequency of the second reception band.

With the above configuration, it is possible to attenuate the harmonic wave components (particularly, second harmonic waves) of the first reception signal and the harmonic wave components (particularly, second harmonic waves) of the second reception signal in the attenuation filter 6.

When the first reception band is the Band 20 reception band (791 MHz to 821 MHz) and the second reception band is the Band 28A reception band (758 MHz to 788 MHz), the lower limit frequency of the Band 20 reception band is 791 MHz and the lower limit frequency of the Band 28A reception band is 758 MHz. Accordingly, the frequency f1 is 1,516 MHz, which is twice 758 MHz. The upper limit frequency of the Band 20 reception band is 821 MHz and the upper limit frequency of the Band 28A reception band is 788 MHz. Accordingly, the frequency f3 is 1,642 MHz, which is twice 821 MHz.

With the above configuration, it is possible to attenuate the second harmonic waves of the reception signal in Band 20 and the reception signal in Band 28A. Accordingly, it is possible to reduce the influence on Global Positioning System (GPS) or Mid-level Band (MLB) the frequency of which is overlapped with the second harmonic waves of the reception signal in Band 20 and the second harmonic waves of the reception signal in Band 28A.

### (2.7) Common Low Noise Amplifier

The common low noise amplifier 3 is a low noise amplifier that is provided between the band pass filter 2 and the attenuation filter 6 on the common path 17, as illustrated in FIG. 1, and that amplifies the first reception signal and the second reception signal. More specifically, the common low noise amplifier 3 is provided between the output terminal 21 of the band pass filter 2 and the input terminal 67 (refer to FIG. 2) of the attenuation filter 6 on the common path 17. The common low noise amplifier 3 amplifies the first reception signal and the second reception signal that have passed through the band pass filter 2. The first reception signal amplified by the common low noise amplifier 3 is supplied to the first low noise amplifier 4 through the first transmission path 15. The second reception signal amplified by the common low noise amplifier 3 is supplied to the second low noise amplifier 5 through the second transmission path 16.

When the common low noise amplifier 3 is not provided, a loss occurs in the attenuation filter 6, which is provided upstream of the first low noise amplifier 4 and the second low noise amplifier 5. This causes a problem in that a noise factor (NF) is degraded.

In order to resolve the above problem, the common low noise amplifier 3 is provided upstream of the attenuation filter 6, as in the present embodiment. The amplification of the first reception signal and the second reception signal by the common low noise amplifier 3 upstream of the attenuation filter 6 enables the influence of the loss downstream of the common low noise amplifier 3 to be reduced. This improves the noise factor. The first low noise amplifier 4 and the second low noise amplifier 5, which are provided downstream of the common low noise amplifier 3, adjust the amplification factors for the first reception signal and the second reception signal.

### (2.8) Switches

The switch 71 is provided between the common terminal 11 and the band pass filter 2, as illustrated in FIG. 1. Two or more filters (not illustrated in FIG. 1) are connected to the switch 71 so as to be parallel to the band pass filter 2. The switch 71 has a common terminal 711 and multiple selection terminals 712. The common terminal 711 is electrically connected to the common terminal 11. In other words, the common terminal 711 is directly or indirectly connected to the common terminal 11. The multiple selection terminals 712 correspond to the multiple filters (including the band pass filter 2) in one-to-one correspondence and are electrically connected to the corresponding filters. In other words, the multiple selection terminals 712 are directly or indirectly connected to the corresponding filters. The switch 71 selects the destination to which the common terminal 711 is connected from the multiple selection terminals 712.

The switch 72 is provided between the band pass filter 2 and the common low noise amplifier 3. Two or more filters (not illustrated in FIG. 1) are connected to the switch 72 so as to be parallel to the band pass filter 2. The switch 72 has a common terminal 721 and multiple selection terminals 722. The common terminal 721 is electrically connected to the common low noise amplifier 3. In other words, the common terminal 721 is directly or indirectly connected to the common low noise amplifier 3. The multiple selection terminals 722 correspond to the multiple filters (including the band pass filter 2) in one-to-one correspondence and are electrically connected to the corresponding filters. In other words, the multiple selection terminals 722 are directly or indirectly connected to the corresponding filters. The switch 72 selects the destination to which the common terminal 721 is connected from the multiple selection terminals 722.

The switch 73 is provided between the first low noise amplifier 4 and the second low noise amplifier 5 and the multiple terminals 12 to 14. Two or more circuit elements (including another low noise amplifier) are connected to the switch 73 so as to be parallel to the first low noise amplifier 4 and the second low noise amplifier 5. The switch 73 has multiple terminals 731 to 733 and multiple terminals 734 to 737. The terminal 731 is electrically connected to the terminal 12. In other words, the terminal 731 is directly or indirectly connected to the terminal 12. The terminal 732 is electrically connected to the terminal 13. In other words, the terminal 732 is directly or indirectly connected to the terminal 13. The terminal 733 is electrically connected to the terminal 14. In other words, the terminal 733 is directly or indirectly connected to the terminal 14. The terminal 734 is electrically connected to the first low noise amplifier 4. In other words, the terminal 734 is directly or indirectly connected to the first low noise amplifier 4. The terminal 735 is electrically connected to the second low noise amplifier 5. In other words, the terminal 735 is directly or indirectly connected to the second low noise amplifier 5. The switch 73 selects the destination to which each of the multiple terminals 731 to 733 is connected from the multiple terminals 734 to 737.

### (3) Communication Apparatus

The communication apparatus 8 includes the radio-frequency module 1, the RF signal processing circuit 81, and a baseband signal processing circuit 82, as illustrated in FIG. 1. The RF signal processing circuit 81 and the baseband signal processing circuit 82 compose a signal processing circuit 80 that processes the first reception signal and the second reception signal.

### (3.1) RF Signal Processing Circuit

The RF signal processing circuit 81 is, for example, a radio frequency integrated circuit (RFIC) and is provided between the radio-frequency module 1 and the baseband signal processing circuit 82, as illustrated in FIG. 1. The RF signal processing circuit 81 has a function to perform signal processing to the first reception signal and the second reception signal received through the antenna 9 and a function to perform signal processing to a first transmission signal and a second transmission signal from the baseband signal processing circuit 82.

### (3.2) Baseband Signal Processing Circuit

The baseband signal processing circuit 82 is, for example, a baseband integrated circuit (BBIC) and is electrically connected to the RF signal processing circuit 81, as illustrated in FIG. 1. The baseband signal processing circuit 82 generates an I-phase signal and a Q-phase signal from a baseband signal. The baseband signal processing circuit 82 performs IQ modulation by combining the I-phase signal with the Q-phase signal to output the first transmission signal and the second transmission signal. At this time, the first transmission signal and the second transmission signal are each generated as a modulation signal resulting from amplitude modulation of a carrier signal of a predetermined frequency with a period longer than the period of the carrier signal.

### (4) Advantages

In the radio-frequency module 1 according to the embodiment, the attenuation filter 6 is provided on the common path 17 between the band pass filter 2 and the first low noise amplifier 4 and between the band pass filter 2 and the second low noise amplifier 5. Accordingly, since the number of the filters is decreased, compared with a case in which the attenuation filter for the first reception signal and the attenuation filter for the second reception signal are separately provided, it is possible to achieve space saving and a reduction in cost.

In the radio-frequency module 1 according to the embodiment, the attenuation filter 6 attenuates the harmonic wave components of the first reception signal and the harmonic wave components of the second reception signal. This enables the harmonic wave components of the first reception signal and the harmonic wave components of the second reception signal to be efficiently attenuated, compared with a case in which the attenuation filter for attenuating the harmonic wave components of the first reception signal and the attenuation filter for attenuating the harmonic wave components of the second reception signal are separately provided. In other words, it is possible to efficiently attenuate the harmonic wave components of the first reception signal and the harmonic wave components of the second reception signal while achieving the space saving and the reduction in cost.

In the radio-frequency module 1 according to the embodiment, the first reception signal conforms to the 4G standard and the second reception signal is a signal conforming to the 5G standard. The radio-frequency module 1 supports the concurrent use of communication of the signal conforming to the 4G standard and communication of the signal conforming to the 5G standard. Accordingly, the radio-frequency module 1 supports the dual connectivity.

In the radio-frequency module 1 according to the embodiment, the common low noise amplifier 3 provided between the band pass filter 2 and the attenuation filter 6 amplifies the first reception signal and the second reception signal. Accordingly, it is possible to increase the noise figure (NF).

### (5) Modifications

Modifications of the embodiment will now be described.

As a modification of the embodiment, the radio-frequency module 1 may include an attenuation filter 6a illustrated in FIG. 4.

The attenuation filter 6a is provided on the common path 17 (refer to FIG. 1), like the attenuation filter 6 (refer to FIG. 1), and attenuates the harmonic wave components of the first reception signal and the harmonic wave components of the second reception signal. The common path 17 is a transmission path formed between the output terminal 21 (refer to FIG. 1) of the band pass filter 2 and the first low noise amplifier 4 (refer to FIG. 1) and between the output terminal 21 of the band pass filter 2 and the second low noise amplifier 5 (refer to FIG. 1), as described above.

The attenuation filter 6a is a low pass filter illustrated in FIG. 4. The attenuation filter 6a has multiple (two in the example in FIG. 4) capacitors 61a and 62a, an inductor 64a, an input terminal 67a, and an output terminal 68a.

The capacitor 61a is provided between a node N4 on a path P2 between the input terminal 67a and the output terminal 68a and the ground.

The capacitor 62a is provided between a node N5 on the path P2 and the ground. The capacitor 62a is connected in parallel to the capacitor 61a. The node N5 is positioned at the output terminal 68a side, compared with the node N4, on the path P2. Accordingly, the capacitor 62a is provided at the output terminal 68a side, compared with the capacitor 61a, on the path illustrated in FIG. 4.

The attenuation filter 6a has an attenuation characteristic illustrated in FIG. 5 because the attenuation filter 6a has the circuit configuration illustrated in FIG. 4. FIG. 5 indicates level representation with respect to the attenuation. Specifically, the attenuation at each frequency is represented by the logarithm of the ratio with respect to the attenuation at the lower-side frequency. The attenuation filter 6a is designed so that the attenuation in a frequency band higher than or equal to the frequency f1 is lower than or equal to the necessary attenuation IL1 [dB]. The frequency f1 is a frequency twice the lower frequency, among the lower limit frequency of the first reception band and the lower limit frequency of the second reception band.

With the above configuration, it is possible to attenuate the harmonic wave components (particularly, the second harmonic waves) of the first reception signal and the harmonic wave components (particularly, the second harmonic waves) of the second reception signal in the attenuation filter 6a, as in the attenuation filter 6.

When the first reception band is the Band 20 reception band (791 MHz to 821 MHz) and the second reception band is the Band 28A reception band (758 MHz to 788 MHz), the lower limit frequency of the Band 20 reception band is 791 MHz and the lower limit frequency of the Band 28A reception band is 758 MHz. Accordingly, the frequency f1 is 1,516 MHz, which is twice 758 MHz.

With the above configuration, it is possible to attenuate the second harmonic waves of the reception signal in Band 20 and the second harmonic waves of the reception signal in Band 28A. Accordingly, it is possible to reduce the influence on the GPS or the MLB the frequency of which is overlapped with the second harmonic waves of the reception signal in Band 20 and the second harmonic waves of the reception signal in Band 28A.

As a modification of the embodiment, the radio-frequency module 1 may include a band pass filter as the attenuation filter 6. The attenuation filter 6 of the present modification uses a frequency band including the frequency of fundamental waves (fundamental frequency) of the first reception signal and the second reception signal as a passband and uses a frequency band lower than the lower limit frequency of the passband and a frequency band higher than the upper limit frequency of the passband as stopbands.

Also in the attenuation filter 6 of the present modification, it is possible to attenuate the harmonic wave components of the first reception signal and the harmonic wave components of the second reception signal.

In addition, the band pass filter 2 is not limited to the reception filter allowing the passage of only the reception signals and may be a time division duplex (TDD) filter. The TDD filter allows the passage of the reception signals and the transmission signals through TDD.

Furthermore, the second reception signal is not limited to the reception signal in Band 28A (reception band: 758 MHz to 788 MHz) and may be a reception signal in another reception band. The second reception signal may be, for example, a reception signal in Band 71 (reception band: 617 MHz to 652 MHz) or a reception signal in Band 41 (2,496 MHz to 2,690 MHz).

The same advantages as in the radio-frequency module 1 according to the embodiment are achieved also in the radio-frequency module 1 according to the respective modifications described above.

The embodiment and the modifications described above are only part of various embodiments and modifications of the present disclosure. The embodiment and the modifications may be subjected to various changes depending on the design.

### (Aspects)

The following aspects are disclosed in this description.

A radio-frequency module (1) according to a first aspect includes a band pass filter (2), a first low noise amplifier (4), a second low noise amplifier (5), and an attenuation filter (6; 6a). The band pass filter (2) has an output terminal (21) and allows the passage of a first reception signal and a second reception signal. The first low noise amplifier (4) is connected to the output terminal (21) of the band pass filter (2) and amplifies the first reception signal. The second low noise amplifier (5) is connected to the output terminal (21) of the band pass filter (2) and amplifies the second reception signal. The attenuation filter (6) is provided on a common path (17) between the output terminal (21) of the band pass filter (2) and the first low noise amplifier (4) and between the output terminal (21) of the band pass filter (2) and the second low noise amplifier (5).

With the radio-frequency module (1) according to the first aspect, since the number of the filters is decreased, compared with a case in which the attenuation filter for the first reception signal and the attenuation filter for the second reception signal are separately provided, it is possible to achieve the space saving and the reduction in cost.

In the radio-frequency module (1) according to a second aspect, in the first aspect, the attenuation filter (6) is a notch filter, a low pass filter, or a band pass filter.

In the radio-frequency module (1) according to a third aspect, in the first or second aspect, the attenuation filter (6) attenuates harmonic wave components of the first reception signal and harmonic wave components of the second reception signal.

With the radio-frequency module (1) according to the third aspect, the harmonic wave components of the first reception signal and the harmonic wave components of the second reception signal are capable of being efficiently attenuated, compared with a case in which the attenuation filter for attenuating the harmonic wave components of the first reception signal and the attenuation filter for attenuating the harmonic wave components of the second reception signal are separately provided. In other words, it is possible to efficiently attenuate the harmonic wave components of the first reception signal and the harmonic wave components of the second reception signal while achieving the space saving and the reduction in cost.

In the radio-frequency module (1) according to a fourth aspect, in one of the first to third aspects, the first reception signal is a signal conforming to a 4G standard. The second reception signal is a signal conforming to a 5G standard. The radio-frequency module (1) supports the concurrent use of communication of the signal conforming to the 4G standard and communication of the signal conforming to the 5G standard.

With the radio-frequency module (1) according to the fourth aspect, the radio-frequency module (1) is caused to support the concurrent use of communication of the signal conforming to the 4G standard and communication of the signal conforming to the 5G standard, that is, the dual connectivity.

The radio-frequency module (1) according to a fifth aspect further includes a common low noise amplifier (3), in one of the first to fourth aspects. The common low noise amplifier (3) is provided between the band pass filter (2) and the attenuation filter (6; 6a) on the common path (17) and amplifies the first reception signal and the second reception signal.

With the radio-frequency module (1) according to the fifth aspect, it is possible to increase the noise figure (NF).

In the radio-frequency module (1) according to a sixth aspect, in one of the first to fifth aspects, the band pass filter (2) is a reception filter or a TDD filter. The reception filter allows the passage of only reception signals including the first reception signal and the second reception signal. The TDD filter allows the passage of the reception signals and transmission signals through TDD.

In the radio-frequency module (1) according to a seventh aspect, in one of the first to sixth aspects, the second reception signal is a reception signal in Band 28A, a reception signal in Band 71, or a reception signal in Band 41.

In the radio-frequency module (1) according to an eighth aspect, in one of the first to seventh aspects, the first reception signal is a signal in a first reception band. The second reception signal is a signal in a second reception band. The second reception band is part of a frequency band of the first reception band.

A communication apparatus (8) according to a ninth aspect includes the radio-frequency module (1) according to one of the first to eighth aspects and a signal processing circuit (80). The signal processing circuit (80) processes the first reception signal and the second reception signal.

With the communication apparatus (8) according to the ninth aspect, in the radio-frequency module (1), since the number of the filters is decreased, compared with a case in which the attenuation filter for the first reception signal and the attenuation filter for the second reception signal are separately provided, it is possible to achieve the space saving and the reduction in cost.

### REFERENCE SIGNS LIST

1 radio-frequency module

11 common terminal

12 to 14 terminal

15 first transmission path

16 second transmission path

17 common path

2 band pass filter

21 output terminal

3 common low noise amplifier

4 first low noise amplifier

5 second low noise amplifier

6, 6a attenuation filter

61 to 63, 61a, 62a capacitor

64 to 66, 64a inductor

67, 67a input terminal

68, 68a output terminal

691 to 693 series circuit

71 switch

711 common terminal

712 selection terminal

72 switch

721 common terminal

722 selection terminal

73 switch

731 to 737 terminal

8 communication apparatus

80 signal processing circuit

81 RF signal processing circuit

82 baseband signal processing circuit

9 antenna

P1, P2 path

N1 to N5 node

f1 to f3 frequency

IL1 necessary attenuation

1. A radio-frequency module comprising:
a band pass filter that has an output terminal, and that is configured to pass a first reception signal and a second reception signal;
a first low noise amplifier that is connected to the output terminal of the band pass filter, and that is configured to amplify the first reception signal;
a second low noise amplifier that is connected to the output terminal of the band pass filter, and that is configured to amplify the second reception signal; and
an attenuation filter that is in a common path between the output terminal of the band pass filter and the first low noise amplifier and between the output terminal of the band pass filter and the second low noise amplifier.

2. The radio-frequency module according to claim 1, wherein the attenuation filter is a notch filter.

3. The radio-frequency module according to claim 1, wherein the attenuation filter is a low pass filter.

4. The radio-frequency module according to claim 1, wherein the attenuation filter is a band pass filter.

5. The radio-frequency module according to claim 1, wherein the attenuation filter is configured to attenuate harmonic wave components of the first reception signal and harmonic wave components of the second reception signal.

6. The radio-frequency module according to claim 1,
wherein the first reception signal is a signal conforming to a fourth generation (4G) standard,
wherein the second reception signal is a signal conforming to a fifth generation (5G) standard, and
wherein the radio-frequency module is configured to concurrently communicate the first reception signal conforming to the 4G standard and the second reception signal conforming to the 5G standard.

7. The radio-frequency module according to claim 1, further comprising:
a common low noise amplifier that is between the band pass filter and the attenuation filter in the common path, and that is configured to amplify the first reception signal and the second reception signal.

8. The radio-frequency module according to claim 1, wherein the band pass filter is a reception filter that is configured to pass only reception signals including the first reception signal and the second reception signal, or the band pass filter is a time division duplex (TDD) filter that is configured to pass the first and second reception signals and transmission signals through TDD.

9. The radio-frequency module according to claim 1, wherein the second reception signal is a reception signal in Band 28A, a reception signal in Band 71, or a reception signal in Band 41.

10. The radio-frequency module according to claim 1,
wherein the first reception signal is a signal in a first reception band, and
wherein the second reception signal is a signal in a second reception band, the second reception band being part of a frequency band of the first reception band.

11. A communication apparatus comprising:
the radio-frequency module according to claim 1; and
a signal processing circuit configured to process the first reception signal and the second reception signal.
